(19) United States
(12) Patent Application Publication
(10) Pub. No.: US 2008/0047701 A1
(43) Pub. Date: Feb. 28, 2008

(54) ELECTROWETTING BASED HEAT SPREADER

(75) Inventors: Vaibhav A. Bahadar, West Lafayette, IN (US); Suresh V. Garimella, West Lafayette, IN (US)

Correspondence Address: BAKER & DANIELS LLP, 300 NORTH MERIDIAN STREET, SUITE 2700, INDIANAPOLIS, IN, 46204, US

(73) Assignee: PURDUE RESEARCH FOUNDATION, West Lafayette, IN (US)

(21) Appl. No.: 11/752,702

(22) Filed: May 23, 2007

Related U.S. Application Data
(60) Provisional application No. 60/747,980, filed on May 23, 2006.

(51) Int. Cl. A47J 39/00; H05K 7/20

(52) U.S. Cl. 165/201; 165/104.23; 165/11.1; 361/699

(57) ABSTRACT

A heat transfer device is disclosed that includes a plurality of electrodes that direct droplets to and from a hot spot to transfer heat from the hot spot to a filler fluid surrounding the droplet.

### RELATED APPLICATIONS

The present application claims priority to U.S. Provisional Patent Application Ser. No. 60/747,980, entitled “ELECTROWETTING BASED HEAT SPREADER,” filed May 23, 2006, to Bahadur et al., the entire disclosure of which is expressly incorporated by reference herein.

### BACKGROUND AND SUMMARY OF THE INVENTION

The present invention relates generally to heat transfer apparatus. More particularly, the present invention relates to an apparatus using electrowetting (EW) to transfer heat.

According to one aspect, a heat transfer device is provided that includes a filler fluid positioned adjacent an area to be cooled, a plurality of droplets, and a plurality of electrodes selectively receiving voltage to control the position of the plurality of droplets. The electrodes direct at least one droplet to a hot spot on the area to be cooled to receive heat from the hot spot and directs the droplet away from the hot spot into the filler fluid to be cooled by the filler fluid.

According to another aspect, a heat transfer device is provided that includes a filler fluid positioned adjacent an area to be cooled, a plurality of droplets, and means for directing the plurality of droplets to portions of the area with elevated temperature and directing the plurality of droplets between the portions with elevated temperature to portions of the area with lowered temperature so that heat is transported from the portions with elevated temperature to the areas with lowered temperature.

According to another aspect, a method for transferring heat is provided including the steps of providing a filler fluid positioned adjacent an area to be cooled and a plurality of droplets, the area having at least one hot spot, moving at least one of the droplets to the hot spot with electrowetting, transferring heat from the hot spot to the at least one droplet, moving the at least one droplet away from the hot spot to a portion of the area spaced apart from the hot spot and surrounded by filler fluid with electrowetting, and transferring a majority of the heat received from the hot spot to the filler fluid.

Additional features of the present invention will become apparent to those skilled in the art upon consideration of the following detailed description of the presently perceived best mode of carrying out the invention.

### BRIEF DESCRIPTION OF THE DRAWINGS

The detailed description of the drawings particularly refers to the accompanying figures in which:

FIG. 1 is a top plan view of a heat transfer device placed over a microchip with the microchip having a plurality of hot spots and the heat transfer device having a plurality of cooling droplets positioned near the hot spots to remove heat from the hot spots of the microchip;

FIG. 2 is a side view of the chip and heat transfer device of FIG. 1 showing a droplet sandwiched between plates of the heat transfer device;

FIG. 3 is a graph showing the velocity of the cooling droplets in response to the voltage applied to the electrodes of the heat transfer device; and

FIG. 4 is a graph showing the heat flux removal capacity as a function of the hot spot temperatures.

### DETAILED DESCRIPTION OF ILLUSTRATIVE EMBODIMENTS

The embodiments disclosed below are not intended to be exhaustive or to limit the invention to the precise forms disclosed in the following detailed description. Rather, the embodiments are chosen and described so that others skilled in the art may utilize their teachings.

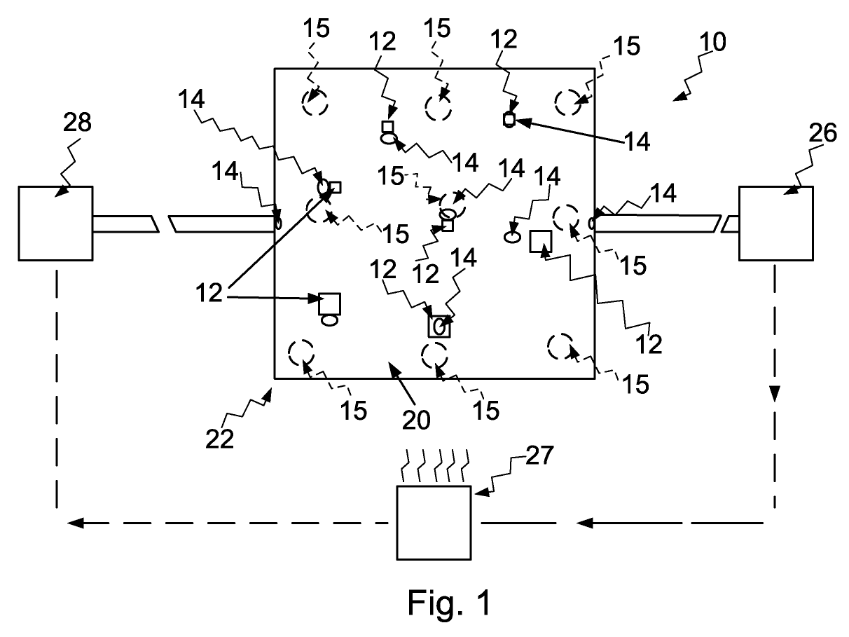

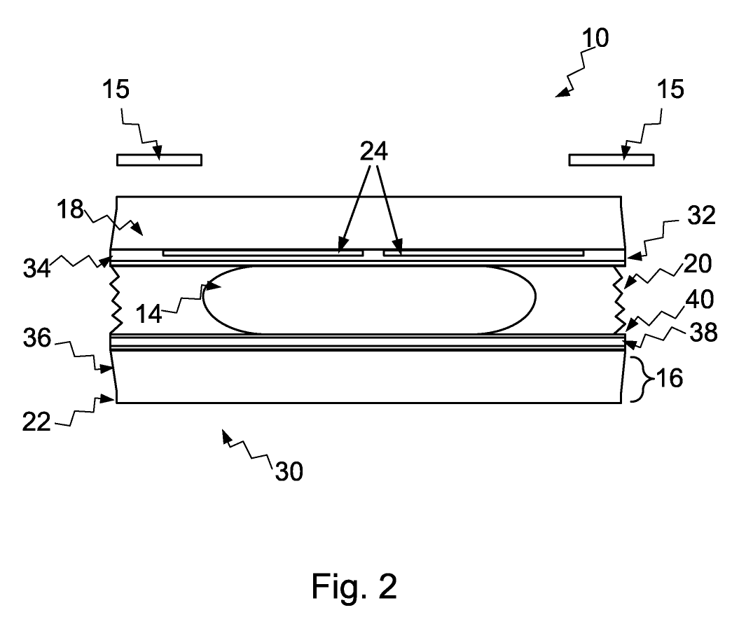

As shown in FIGS. 1 and 2, a heat transfer device 10 is provided for spreading heat from heat sources and hot spots 12, to maintain the hot spot temperatures below the maximum permissible value. A droplet 14 of thermally conducting fluid (such as water) is oscillated over hot spots 12 by employing electrowetting based droplet actuation. As shown in FIG. 2, droplet 14 is sandwiched between a hot surface 16 and an additional top plate 18, and is surrounded by a non-evaporating filler fluid 20 of high thermal conductivity. Droplet motion is controlled by the actuation voltage and the electrode layout on top plate 18.

For the case when the filler fluid temperature is less than the droplet temperature, droplet 14 picks up heat from hot spot 12 and transfers part of it to the colder surrounding filler fluid 20 during each oscillatory cycle. When a droplet 14 above a particular hot spot 12 becomes too hot to maintain sufficient heat transfer, it is moved to a cooler region within filler fluid 20 (such as one of the corners of the chip shown in FIG. 1) and replaced by another droplet 14 having a cooler temperature to provide sufficient heat transfer at hot spot 12. The replaced droplet 14 transfers heat to the colder surrounding filler fluid 20 with or without oscillation. When the replaced droplet 14 is sufficiently cooled, it can be used to replace another droplet 14 that is too hot to maintain sufficient heat transfer. This self cooling action of droplets 14 within the region of filler fluid 20 obviates the need for external cooling of droplets 14.

For the case of the filler fluid temperature being greater than the droplet temperature, droplet 14 would pick up heat from filler fluid 20 in addition to hot spot 12. In this case, droplet 14 is moved away from hot spot 12 when it reaches a threshold temperature, and is replaced by a new cold droplet 14. The hot droplet 14 is pumped away to a fluid reservoir for external cooling, prior to recirculation.

Droplet motion throughout the entire droplet life cycle is controlled by electrowetting based pumping action, which has very low power consumption. This heat spreading mechanism based on electrowetting induced droplet motion can be used in place of conventional heat spreaders as well as for hot spot thermal management of microelectronic chips, resulting in lower temperature gradients in the chip, reduced thermal stresses, lower overall chip temperatures and increased reliability.

This technology can be used to design heat spreading devices for various heat transfer applications. In particular this technology can be used for hot spot thermal management of microelectronic chips which have specified maximum temperature limits to ensure long term reliability. This technology can be used to control hot spot temperatures by extracting and spreading away heat from hot spot 12. The concept of electrowetting induced pumping can also be used to design electrowetting-based microchannel heat sinks, wherein discrete droplets 14 moving in microchannels are used to remove heat from the hot substrate.

Heat transfer device 10 provides localized convective heat extraction with higher heat transfer coefficients, when compared to high thermal conductivity solid materials, ensuring higher heat dissipation capacities than conduction-based spreaders. Heat transfer device 10 affords greater hot spot temperature control possibilities resulting from enhanced control of droplet motion by electrowetting. Heat transfer device 10 provides site-specificity (i.e., dynamic selection of cooling location). Heat transfer device 10 also lends itself easily to integration with microelectronic chips and is totally noiseless. Heat transfer device 10 also has very low power consumption as compared to other heat removing technologies.

Heat transfer device 10 uses localized convective heat removal instead of conduction-based heat spreaders, although such heat spreaders may be used in conjunction with heat transfer device 10. Heat transfer device 10 utilizes a controller, which can be the chip being cooled or another controller that uses feedback from surface thermal sensors 15 to develop dynamic cooling solutions for time varying heat flux situations. Thermal sensors 15 can be used to detect hot spots 12 and to detect when a droplet 14 is above a particular temperature and needs to be replaced by another droplet 14 to maintain sufficient heat transfer as described above. The controller monitors the temperature of droplets 14 using input from heat sensor 15 and directs them to and from hot spots 12 using electrowetting based pumping. Microfabricated thermocouples can be used as thermal sensors 15 which is known to those skilled in the art.

The position of droplets 14 are tracked by the controller. In one tracking method, the controller assumes the respective droplets 14 follow the path specified by the controller. The control can verify that the respective droplet 14 is following the specified path by tracking the thermal signature of respective droplet using thermal sensors 15. If a droplet 14 is “lost” by the controller, the controller selects another droplet 14 to be a replacement.

In many chips, the location of hot spots 12 is predictable based on the layout of heat generating circuitry within the chip. In such circumstances, the location of hot spots 12 can be programmed into the memory of the controller of heat transfer device 10 without any reliance on thermal sensors 15. Movement of droplets 14 to and from hot spots 12 can be controlled based on predetermined timing.

Electrowetting provides reliable and enhanced control of droplet motion. Additional description of electrowetting is provided in U.S. Pat. No. 6,911,132, to Pamula et al.; entitled “Apparatus for manipulating droplets by electrowetting-based techniques;” U.S. Pat. No. 6,565,727 to Shenderov, entitled “Actuators for microfluidics without moving parts;” U.S. Pat. No. 6,629,826, to Yoon et al., entitled “Micropump driven by movement of liquid drop induced by continuous electrowetting;” and U.S. Pat. No. 6,773,566, to Shenderov, entitled, “Electrostatic actuators for microfluidics and methods for using same;” the disclosures of which are expressly incorporated by reference herein. Additional description of hot spot cooling strategies is provided in U.S. Patent Application Publication No. 2005/0212124, to Wang, entitled “Device for cooling hot spot in micro system; “U.S. Patent Application Publication No. 2005/0183844, to Tilton et al., entitled “Hotspot spray cooling; “and U.S. Patent Application Publication No. 2003/0229662, to Luick, entitled “Method and apparatus to eliminate processor core hot spots,” the disclosures of which are expressly incorporated by reference herein.

The working of the electrowetting based heat spreading device 10 is illustrated in FIG. 1 for the case when droplet 14 picks up heat from hot spot 12 as well as filler fluid 20 during each oscillatory cycle. Illustrative microelectronic chip 22 gives out a non-uniform heat flux resulting in multiple hot spots 12 as illustrated in FIG. 1. Water droplets 14 are oscillated around each hot spot 12 by employing electrowetting-based droplet actuation. Droplets 14 are covered by top plate 18 (not shown in FIG. 1) which consists of a two-dimensional network or matrix of actuation electrodes 24 and electrical interconnects (not shown). The matrix of electrodes 24 and related interconnects is based on the predetermined location of hot spots 12, if known, and the preferred size of droplets 14.

Water droplets 14 are surrounded by non-evaporating and thermally conducting filler fluid 20, like silicone oil. Each droplet 14 picks up heat from a respective hot spot 12 and the surrounding filler fluid 20, thereby preventing any further increase in the hot spot temperature. As a respective droplet 14 heats up, its heat dissipation capacity decreases. When the respective droplet 14 reaches a threshold temperature, beyond which the heat dissipation capacity is less than required, the oscillatory motion of the respective droplet 14 is stopped. If a region of filler fluid 20 is less than a predetermined temperature, the “hot” droplet 14 is directed by the controller to that cooler region (such as the corners of chip 22 as shown in FIG. 1), to transfer heat to filler fluid 20 with or without oscillations. This “hot” droplet 14 is replaced by a “cold” droplet 14 by the controller.

If filler fluid 20 is above a predetermined temperature, the respective droplet 14 is then withdrawn to a hot fluid reservoir 26 for external cooling by an external heat transfer device 27, such as a heat exchanger before recirculation. This droplet 14 is replaced by a new cold droplet 14 which is created from a cold fluid reservoir 28 and moved over to the respective hot spot 12. In the exemplary embodiment, the motion of the respective droplet 14 throughout its entire life cycle is controlled entirely by the controller and electrodes 24 using electrowetting. According to other embodiments, portions of the motion may be provided by other means than electrowetting. If filler fluid 20 is sufficiently cooled, external cooling is not provided using reservoirs 26, 28 and external heat transfer device 27. Thus, in some embodiments, external reservoirs 26, 28 and external heat transfer device 27 are not provided.

A cross section of an EW-based spreading device 10 is shown in FIG. 2. Heated lower plate 30 and top plate 18 are separated by a selected spacing. Control electrodes 24 are positioned or fabricated on top plate 18 such that they can be individually addressed and connected to electrical interconnects. Control electrodes 24 are covered by a dielectric layer 32 (1 μm parylene) and a hydrophobic layer 34 (50 nm Teflon). Heated lower plate 30 is covered by a single, grounded electrode plane 36 which is also coated with a dielectric layer 38 (0.1 μm parylene) and a hydrophobic layer 40 (50 nm Teflon). According to the exemplary embodiment, the droplet size is chosen to be slightly larger than the electrode pitch so that it overlaps more than one electrode 24. According to one embodiment of the present disclosure, lower plate 30 is the upper surface of chip 22 to facilitate direct heat removal from chip 22. According to other embodiments, other surfaces of chip 22 may be cooled, such as the bottom surface.

When a voltage is applied to the right electrode 24 on top plate 18 (shown in FIG. 2) by the controller, the dielectric-liquid interfacial tension on the right end of droplet 14 decreases, and droplet 14 spreads to the right. Droplet 14 then moves towards the energized electrode 24 and reaches equilibrium when it is at the center of the energized electrode. The electric field induced reduction of dielectric-liquid interfacial tension thus provides the motive force for droplet actuation. Enhanced and accurate control of droplet motion can be achieved with proper electrode layouts and voltage variations. To continue moving droplet 14 to the right, voltage is applied to the next electrode to the right (not shown) and the voltage to the previous electrode 24 is removed. By sequentially applying the voltage to electrodes 24 droplets 14 are moved about and oscillated by the controller.

The EW induced actuation force on a droplet 14 is modeled by using the principle of energy minimization. EW actuation results from a reduction in the dielectric-liquid interfacial energy in the presence of an applied voltage. The total droplet surface energy is estimated as a function of the transition position of the droplet. The energy gradient gives the actuation force on a droplet 14 at that position. This actuation force model is combined with semi-empirical models which predict the forces opposing droplet motion to yield a model which predicts EW induced droplet motion. The significant opposing forces consist of the shear force from the top and bottom plates 18, 30, the viscous force offered by filler fluid 20, and the contact-line friction force. Equation (1) represents the model to predict transient EW induced droplet motion of a rectangular droplet.

$$m \frac{{ⅆ}^{2} x}{ⅆ {t}^{2}} = \frac{k {ɛ}_{0} {V}^{2} b}{2 t} - \frac{12 {μ}_{l} l b}{d} ( \frac{ⅆ x}{ⅆ t} ) - \frac{C {ρ}_{f} bd}{2} {( \frac{ⅆ x}{ⅆ t} )}^{2} - 4 ζ ( l + b ) ( \frac{ⅆ x}{ⅆ t} ) \qquad ( 1 )$$

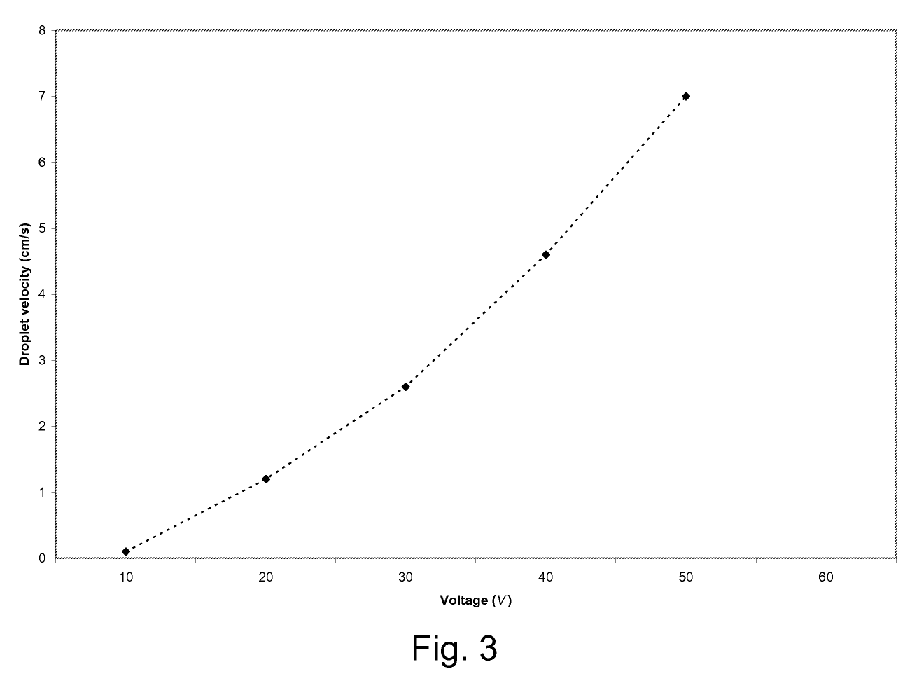

FIG. 3 plots the steady state transition velocity of a rectangular droplet as a function of the actuation voltage. The droplet velocity depends on the applied voltage with a velocity of 7 cm/s obtained for a voltage of 50 V.

The hot spot cooling capacity resulting from droplet motion can be estimated by a transient thermal analysis of a droplet 14 oscillating around a hot spot 12. The cooling capacity is measured in terms of the heat flux dissipation at a specified hot spot temperature (which prevents any further temperature rise). A droplet 14 picks up heat from a hot spot 12 as well as surrounding filler fluid 20, which is assumed to be at a fixed lower temperature than the respective hot spot 12. A 1 mm square hot spot 12 is analyzed and a rectangular droplet 14 is oscillated around the respective hot spot 12. The droplet dimensions and the oscillation magnitude is chosen to ensure that the respective hot spot 12 is completely covered by droplet 14 during all stages of the oscillation. The droplet temperature is allowed to reach a maximum permissible value, after which droplet 14 is moved away from hot spot 12 by EW based pumping and replaced by a new droplet 14 as discussed above.

The equation representing the transient thermal behavior of the droplet is:

$${mcC}_{p} \frac{ⅆ T}{ⅆ t} + {h}_{b} {A}_{b} ( {T}_{h} - T ) + {h}_{s} {A}_{s} ( {T}_{s} - T )$$

where T is the droplet temperature,
Tₕ is the hot spot temperature,
Tₛ is the filler fluid temperature,
hₛ and h_{b} are the heat transfer coefficients at the droplet side and droplet bottom respectively,
Aₛ and A_{b} are the side and top surface areas of the droplet respectively,
Cₚ is the droplet specific heat, and
m is the droplet mass.

Top plate 18 is assumed to be adiabatic in the above analysis. Key dimensions and parameters used in the foregoing analysis are detailed in Table 1.

TABLE 1

| Parameter | Value | |
|---|---|---|
| Droplet inlet temperature | 30° | C. |
| Droplet length | 1.5 | mm |
| Droplet width | 1 | mm |
| Separation between top plate and chip | 0.3 | mm |
| Droplet actuation voltage | 50 | V |

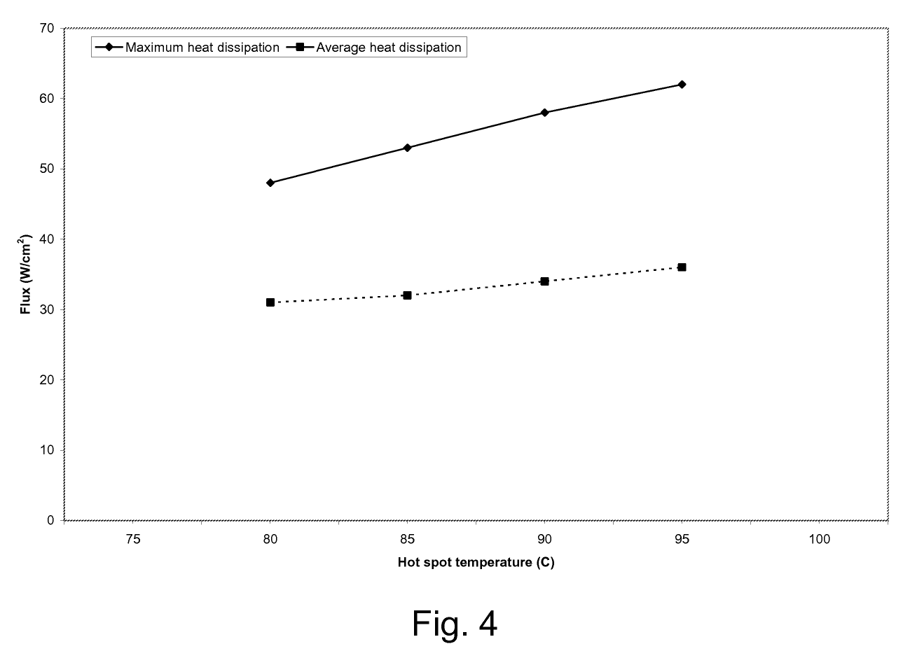

The maximum and average (averaged over the entire cooling duration) heat dissipation capacities were estimated for varying hot spot temperatures. The filler fluid temperature was assumed to be 10° C. less than the hot spot temperature and the maximum permissible droplet temperature was fixed to be 20° C. less than the hot spot temperature. FIG. 4 shows the maximum and average heat transfer capacity of a single droplet 14 with varying hot spot temperatures. The maximum and average cooling capacities increase with the hot spot temperature as expected owing to the greater temperature difference available for heat transfer. The results show that up to 60 W/cm² localized heat dissipation is possible, which offers immense possibilities for hot spot thermal management.

Heat spreading device 10 has very low power consumption. The average power consumption over a droplet oscillation cycle is 4.1 μW. The high heat flux dissipation capacity, low power consumption, noiselessness and ease of integration with the heated surface are features which make electrowetting based heat spreading device 10 attractive for hot spot thermal management.

Although the invention has been described in detail with reference to certain preferred embodiments, variations and modifications exist within the spirit and scope of the invention as described and defined in the following claims.

1. A heat transfer device including
a filler fluid positioned adjacent an area to be cooled,
a plurality of droplets, and
a plurality of electrodes selectively receiving voltage to control the position of the plurality of droplets, the electrodes directing at least one droplet to a hot spot on the area to be cooled to receive heat from the hot spot, and directing the droplet away from the hot spot into the filler fluid to be cooled by the filler fluid.

2. The heat transfer device of claim 1, wherein the droplet directed away from the hot spot remains in the area of the filler fluid and is returned to a hot spot to remove heat after it is cooled by the filler fluid.

3. The heat transfer device of claim 1, wherein the plurality of droplets include water and the filler fluid includes oil.

4. The heat transfer device of claim 1, wherein the location of the hot spot is predetermined and the plurality of electrodes direct the at least one droplet to and from the hot spot based on the predetermined location of the hot spot.

5. The heat transfer device of claim 4, wherein the plurality of electrodes retain the at least one droplet adjacent to the hot spot for a predetermined period of time.

6. The heat transfer device of claim 1, wherein the plurality of electrodes oscillate the plurality of droplets while positioned adjacent to the hot spot.

7. The heat transfer device of claim 6, wherein the plurality of electrodes oscillate the plurality of droplets while being cooled in the filler fluid.

8. The heat transfer device of claim 1, further comprising at least one thermal sensor that provides an input to the selection of the voltage received by the plurality of electrodes.

9. The heat transfer device of claim 1, wherein the at least one droplet receives heat from the hot spot until it reaches a predetermine temperature.

10. The heat transfer device of claim 1, wherein the plurality of electrodes direct the at least one droplet out of the filler fluid to an external heat transfer device when the temperature of the at least one droplet exceeds the temperature of the filler fluid.

11. The heat transfer device of claim 1, wherein the plurality of electrodes retain the at least one droplet within the filler fluid when the temperature of the at least one droplet is less than the temperature of the filler fluid.

12. The heat transfer device of claim 1, wherein the at least one droplet receives heat originating from a microprocessor while positioned adjacent to the hot spot.

13. The heat transfer device of claim 12, wherein the wherein the at least one droplet receives heat origination from a predetermined location on the microprocessor having an elevated concentration of circuits creating the hot spot.

14. A heat transfer device including
a filler fluid positioned adjacent an area to be cooled,
a plurality of droplets, and
means for directing the plurality of droplets to portions of the area with elevated temperature and directing the plurality of droplets between the portions with elevated temperature to portions of the area with lowered temperature so that heat is transported from the portions with elevated temperature to the areas with lowered temperature.

15. The heat transfer device of claim 14, wherein the directing means includes a plurality of electrodes selectively receiving voltage to direct the plurality of droplets.

16. The heat transfer device of claim 15, wherein the plurality of electrodes are arranged in a two-dimensional matrix.

17. A method for transferring heat including the steps of
providing a filler fluid positioned adjacent an area to be cooled and a plurality of droplets, the area having at least one hot spot,
moving at least one of the droplets with electrowetting to the hot spot,
transferring heat from the hot spot to the at least one droplet,
moving the at least one droplet with electrowetting away from the hot spot to a portion of the area spaced apart from the hot spot and surrounded by filler fluid, and
transferring a majority of the heat received from the hot spot to the filler fluid.

18. The method of claim 17, further comprising the step of returning the at least one droplet to a hot spot of the area after the at least one droplet transfers the majority of the heat received from the hot spot to the filler fluid.

19. The method of claim 17, wherein the providing step further includes providing a two-dimensional matrix of electrodes that performs the moving steps.

20. The method of claim 17, wherein the at least one droplet is moved away from the hot spot after the cooling capacity of the at least one droplet is less than a predetermined cooling capacity.
